(19) United States
(12) Patent Application Publication
(10) Pub. No.: US 2011/0198214 A1
(43) Pub. Date: Aug. 18, 2011

(54) MESOPOROUS SILICA FILM AND PROCESS FOR PRODUCTION THEREOF

(75) Inventors: Hirokatsu Miyata, Hadano-shi (JP); Wataru Kubo, Inagi-shi (JP); Atsushi Kamoto, Moriya-shi (JP)

(73) Assignee: Canon Kabushiki Kaisha, Tokyo (JP)

(21) Appl. No.: 13/126,220

(22) PCT Filed: Nov. 27, 2009
(86) PCT No.: PCT/JP2009/070434

§ 371 Date: Apr. 27, 2011

(30) Foreign Application Priority Data
Dec. 4, 2008 (JP) 2008-310293

(51) Int. Cl. C23C 14/24

(52) U.S. Cl. 204/192.38

(57) ABSTRACT

In a mesoporous silica film formed on a non-single-crystalline carbon film having structural anisotropy on a substrate in-plane arrangement of the pores is controlled in one direction, which is defined by the structural anisotropy of the carbon film.

### TECHNICAL FIELD

The present invention relates to a mesoporous silica film being useful as a low-dielectric film or an optical material film, and a process for producing thereof. More specifically, the present invention relates to a mesoporous silica film having a controlled porous structure in the plane of the film.

### BACKGROUND ART

Porous materials are classified into three groups by the pore sizes: microporous materials (pore size less than 2 nm), mesoporous materials (pore size ranging from 2 nm to 50 nm), and macroporous materials (pore size larger than 50 nm). Those porous materials are used in various fields such as adsorption, and separation. Microporous materials represented by zeolite have pores with a diameter of about 1.5 nm at the largest, and are applied widely as catalysts. Therefore, porous material having a larger and uniform pore diameter is demanded for synthesis of a functional hybrid material by combining polymeric or biological materials.

Mesoporous material, which are prepared using molecular assemblies of a surfactant as the template, have mesopores with a uniform pore size, and in many cases, the mesopores are regularly arranged. The mesoporous materials include those with various mesoporous structures such as two-dimensional hexagonal structure having honeycomb-packed cylindrical mesopores, and three-dimensional hexagonal structure/cubic structure having close-packed spherical mesopores.

The regular arrangement of mesopores in mesoporous materials resembles the regular arrangement of atoms in crystals, which provides clear X-ray diffraction patterns similar to crystalline materials. However, the structural period is one order longer than that of crystals, therefore the diffraction peaks appear at smaller angle regions than those of the crystals. Mesoporous silica is a representative of mesoporous materials. However, many mesoporous materials other than the silica, such as transition metal oxides, have been reported recently Generally, those containing molecular assemblies of a surfactant as a template in the mesopores are called as mesostructured materials, and those with hollow mesopores prepared by removing the surfactant by calcination or extraction are called as mesoporous materials. However, in the present invention, those containing surfactant assemblies in the pores are also included in mesoporous material.

For industrial application of mesoporous materials having regular porous structures to functional materials, formation of these materials as a uniform film on a substrate is important. The formation of uniform mesoporous films can be achieved, for example, by spin coating or dip coating methods based on the sol-gel chemistry, as described in Non-Patent Document 1 and Non-Patent Document 2, or by hydrothermal synthesis on a solid surface as described in Non-Patent Document 3.

In the films formed on a substrate by the above film forming method, the orientation of the mesopores in the direction of the film thickness is fixed with respect to the substrate surface, and the pore structures are sometimes regular at microscopic scales. However, the pore arrangement direction is generally random in the plane of the film. In the case of spherical pores, small domains are formed in which the pores are arranged in different directions in the plane each other, while in the case of cylindrical pores, the cylinders are meandering within the film plane.

When the in-plane arrangement of the mesopores is not controlled, the film becomes macroscopically isotropic despite the anisotropy of the local porous structure. Consider, for example, mesoporous materials having cylindrical mesopores. A single cylindrical mesopore provides a highly anisotropic nano-space. However, as a whole film, the anisotropy of the individual cylindrical pores is canceled by the random orientation of the cylindrical mesopores.

Therefore, films of composite materials with macroscopically anisotropic properties can be prepared if the in-plane arrangement of the mesopores can be controlled over the whole film. Several techniques are known for controlling the pore arrangement within the plane of the meso-porous silica film. Patent Document 1 discloses a technique for the orientation control by utilizing a crystalline surface having a two-fold symmetry. Patent Documents 2 and 3 disclose a technique for the orientation control of mesopores by utilizing an oriented polymer film. Patent Document 4 discloses a technique for the orientation control by utilizing a photoreactive polymer film treated by polarized light irradiation

Several applications of mesoporous films with controlled in-plane porous structure have been reported. For example, a light-emitting composite film with low pumping threshold intensity for lasing is disclosed. This film is prepared by incorporating a light-emitting semiconducting polymer compound into the uniaxially aligned cylindrical mesopores of a meso-porous silica film. (Non-Patent Document 4)
[Patent Document 1] Japanese Patent No. 4077970
[Patent Document 2] Japanese Patent No. 3587373
[Patent Document 3] Japanese Patent Application Laid-Open No. 2005-246369
[Patent Document 4] Japanese Patent Application Laid-Open No. 2005-272532
[Non-Patent Document 1] Chemical Communications vol. 1996, p. 1149
[Non-Patent Document 2] Nature, vol. 389, p. 364
[Nom-Patent Document 3] Nature, vol. 379, p. 703
[Non-Patent Document 4] Nature Nanotechnology, vol. 2, p. 647

### DISCLOSURE OF THE INVENTION

### Problems to be Solved by the Invention

In the technique disclosed in Patent Document 1, the substrate is limited to a single crystalline substrate.

In the technique disclosed in Patent Documents 2 and 3 do not limit the substrate material. However, the polymer film on the substrate surface needs to be mechanically contacted for orienting the polymer chains in one direction, which limits the shape of the substrate to be planer. Further, the orientation of the mesopores sometimes becomes nonuniform within the substrate. although this technique allows fine control of in-plane orientation of mesopores.

In the technique disclosed in Patent Document 4, although the orientation of the polymer chains is achieved without contacting to the substrate surface, complicated synthesis of a photo-crosslinkable polymer is necessary. Further, two-times ultraviolet irradiation with a heat treatment between the each irradiation treatment are required, which makes the preparation process complicated. Furthermore, the distribution of the orientation direction of mesopores is relatively wide, suggesting the relatively low degree of in-plane orientation.

The present invention intends to solve the above problems. The present invention provides a mesoporous silica film which has high uniformity in the in-plane arrangement of the pores in a mesoporous silica film formed on a substrate, even on a curved one. The present invention further intends to provide a non-contacting simple process for producing a mesoporous silica film with an improved uniformity in the in-plane arrangement of the mesopores.

### Means for Solving the Problem

The present invention is directed to a mesoporous silica film formed on a non-single-crystalline carbon film having structural anisotropy on a substrate, wherein the in-plane arrangement of the pores in the mesoporous silica film is controlled in one direction defined by the structural anisotropy of the carbon film throughout the entire substrate.

In the mesoporous silica film, molecular assemblies of a surfactant can fill the pores.

The non-single-crystalline carbon film having the structural anisotropy can have a columnar structure.

The non-single-crystalline carbon film having the structural anisotropy scatters X-rays at a higher intensity selectively in one direction, in an X-ray scattering intensity profile measured in a reflection mode under the grazing incidence geometry.

The non-single-crystalline carbon film having the structural anisotropy can be a diamond-like carbon film containing carbon having sp³ C—C bonding.

The present invention is directed to a process for producing a mesoporous silica film, comprising the steps of: forming a non-single-crystalline carbon film having structural anisotropy on a substrate, and forming, on the carbon film, a mesostructured silica film with controlled in-plane orientation of the mesopores containing surfactant molecule assemblies.

The non-single-crystalline carbon film having structural anisotropy can be formed by an oblique filtered arc deposition technique.

The mesostructured silica film can be formed by hydrothermal synthesis.

The mesostructured silica film can be formed by a sol-gel method.

The process can further comprise the step of removing the surfactant from the pores.

### Effect of the Invention

The present invention provides a mesoporous silica film which has high uniformity in the in-plane arrangement of the pores in a mesoporous silica film formed on a substrate, even on a curved one. The present invention provides further a non-contacting simple process for producing a mesoporous silica film with an improved uniformity in the in-plane arrangement of the mesopores.

### BRIEF DESCRIPTION OF THE DRAWINGS

FIGS. 1A and 1B illustrates schematically a structure of a mesoporous silica film of the present invention.

FIGS. 2A and 2B illustrates schematically orientation of the pores in the plane of the mesoporous silica film of the present invention.

FIG. 3 is a schematic drawing for describing an oblique deposition method for the formation of a carbon film of the present invention.

FIGS. 4A and 4B are drawings for describing the structure of the carbon film consisted of inclined columns in the present invention.

FIG. 5 illustrates schematically a system of an apparatus for the carbon film formation by filtered arc deposition in the present invention.

FIGS. 6A and 6B illustrate a structure of the mesoporous silica film of the present invention after removing the carbon film by calcination.

FIG. 7 illustrates a example of a apparatus for a dip-coating process in the present invention.

FIG. 8 is a scanning electron micrograph of the cross-section of the non-single crystalline carbon film having structural anisotropy prepared in Example 1 of the present invention.

FIG. 9 is a schematic drawing for describing an arrangement for introduction of an X-ray beam at a grazing incidence angle onto a non-monocrystalline carbon film having structural anisotropy, and measurement of the scattered X-ray intensity in a reflection mode, and an obtained pattern in the present invention.

FIG. 10 shows the pattern obtained by introducing an X-ray beam at a grazing incidence angle onto the structurally anisotropic non-single-crystalline carbon film prepared in Example 1 and measuring the scattered X-ray intensity in a reflection mode, and shows also the inclination angle of the columns estimated from the pattern.

FIG. 11 shows in-plane rocking curves of in-plane X-ray diffraction analysis for evaluation of the distribution of the orientation of the mesopores in the mesoporous silica film prepared by the hydrothermal synthesis on a carbon films deposited at different angles in Example 1 of the present invention.

FIG. 12 shows an in-plane rocking curve of in-plane X-ray diffraction analysis for of the distribution of the arrangement of the mesopores in the mesoporous silica film prepared by the hydrothermal synthesis on a carbon film deposited at 75° in Example 2 of the present invention.

FIG. 13 is a scanning electron micrograph of the cross-section of the obliquely evaporated SiO₂ film used in Comparative Example of the present invention.

The reference numerals in the drawings in the present invention are defined below.
11 Substrate
12 Non-single-crystalline carbon film having structural anisotropy
13 Mesopore
14 Pore wall
15 Mesoporous silica film
16 Species to be deposited
17 Normal direction of substrate
18 Film surface
41 Carbon column
501 Cathode
502 Anode
503 Trigger electrode
504 Acceleration power source
505 Arc power source
506 Plasma duct
507 Toroidal coil
508 Substrate
509 Film formation chamber
510 Electromagnet
511 Valve
71 Vessel
72 Substrate having a non-single-crystalline carbon film having structural anisotropy
73 Precursor solution
74 Substrate holder
75 Rod
76 Z-stage
91 Non-single-crystalline carbon film having structural anisotropy
92 X-ray (beam)
93 Imaging plate
101 Direction of selective increase of scattered X-rays intensity
102 Column inclination angle

### BEST MODE FOR CARRYING OUT THE INVENTION

The present invention is described below in detail.

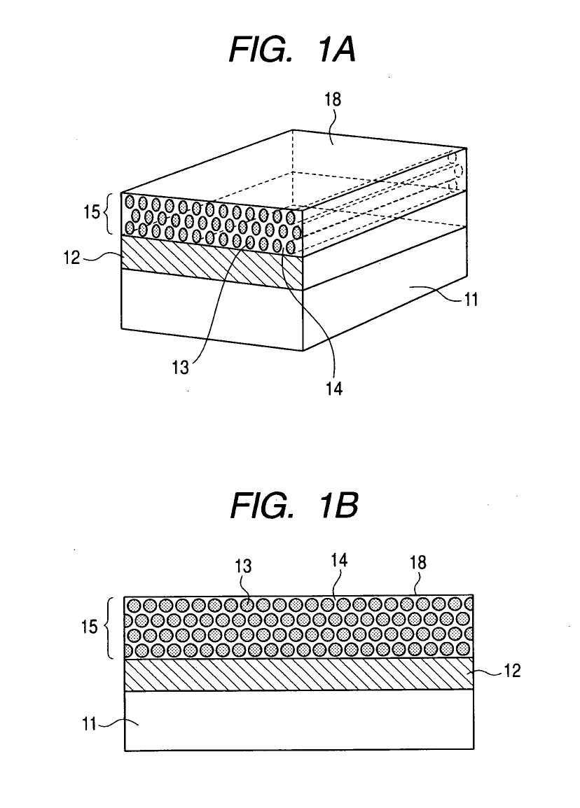

FIGS. 1A and 1B illustrate schematically a structure of a mesoporous silica film of the present invention. FIG. 1A is a perspective schematic view, and FIG. 1B is a sectional view thereof. In FIGS. 1A and 1B, the reference numerals denote the following members: 11, a substrate; 12, a non-single-crystalline carbon film having structural anisotropy; 13, mesopore; 14, pore wall; 15, mesoporous silica film; and 18, film surface.

The mesoporous silica film 15 of the present invention is formed on a substrate, and the arrangement of the pores is controlled in a fixed direction in the film plane.

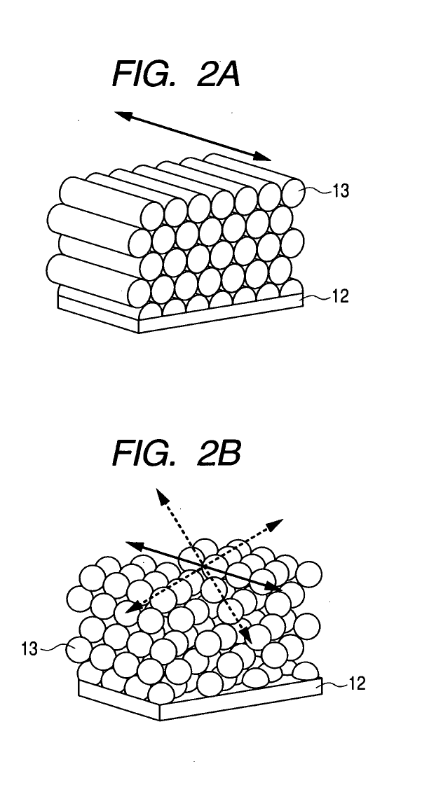

FIGS. 2A and 2B illustrates schematically orientation of the pores in the plane in the mesoporous silica film of the present invention.

In the present invention, the porous structure of the mesoporous silica may be of a two-dimensional hexagonal structure in which cylindrical mesopores 13 are honeycomb-packed. FIGS. 1A and 1B and FIG. 2A illustrate schematically the structure. The hexagonal structure need not be precisely regular hexagonal in the cross-section, but may be in a shape compressed in the film thickness direction to have the mesopores having an ellipsoidal cross-section. In FIG. 2B, the arrow marks indicate the alignment direction of the pores. Of the arrangement directions, one direction may be selected for the arrangement.

The mesoporous silica film of the present invention may have a three-dimensional hexagonal structure in which spherical pores are arranged in a hexagonal close-packed state. An example is shown in FIG. 2B in which the spherical pores are arranged in the same directions in the plane of the film. In the close-packed state, since the spherical pores form triangles in a plane, there are three equivalent arrangement directions in the plane. The spherical pores need not be in a complete sphere shape, but may be in a compressed sphere shape constricted in the vertical direction insofar as the arrangement is controlled in the plane. In FIG. 2B, the arrow marks indicate respectively an arrangement direction.

The porous structure of the mesoporous silica film of the present invention is not limited to the ones mentioned above. The porous structure includes those in which the arrangement direction of the pores is controlled in an entire film plane. For example, a face-centered cubic structure is included which has a close-packed spherical porous structure different in the regularity of the stacking from the above-mentioned three-dimensional hexagonal structure, and need not be in a complete sphere shape similarly as the above-mentioned three-dimensional hexagonal structure. This structure also has three equivalent orientation directions, and one of the three is selected as the orientation direction.

The mesoporous silica film has generally empty pores. However, the mesoporous silica film of the present invention includes also those containing a substance enclosed in the pores. For example, the present invention includes the one including in the pores molecular assemblies of a surfactant employed as a template for pore formation in preparation of the mesoporous silica film, as described later regarding the process for preparing the mesoporous silica film.

In the mesoporous silica film of the present invention, the orientation direction of the pores in the film plane is determined by the non-single-crystalline carbon film 12 having structural anisotropy formed on substrate 11.

Substrate 11 may be any material which is resistant in the process for preparation of the mesoporous silica film, the material including silicon, and quartz glass. The substrate in the present invention may be a flat plate or a curved plate having a finite curvature.

Next, the non-single-crystalline carbon film 12 having structural anisotropy is described below. A carbon film employed preferably in the present invention is formed by a vapor-phase film formation method on a substrate. The process for formation of the carbon film in the present invention includes chemical vapor deposition (CVD), pulse laser deposition (PLD), ion beam sputtering, and cathode arc vapor phase deposition, but is not limited thereto provided that the process is capable of making a carbon films that control the orientation of the pores in a mesoporous silica film.

Usual vapor deposition does not form a structurally anisotropic film. The structural anisotropy herein signifies anisotropy at a several-nanometer scale, which is larger than the atomic scale regularity in the film, excluding, for example, single-crystalline graphite.

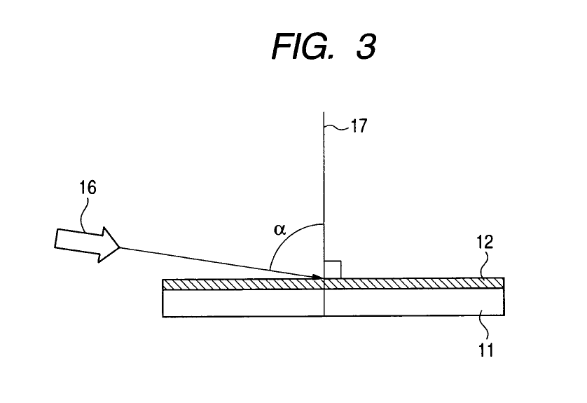

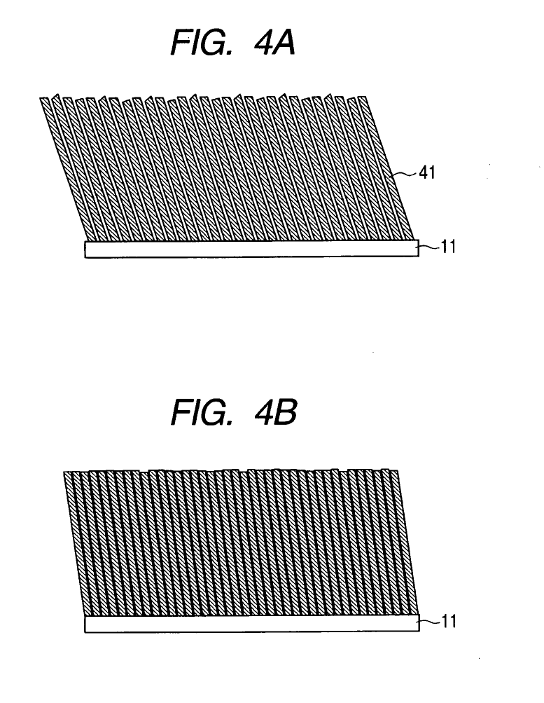

A usual method for forming a carbon film with a structural anisotropy is an oblique deposition method. FIG. 3 is a schematic drawing for describing an oblique deposition method for the formation of a carbon film of the present invention. In the oblique deposition method, the substrate is held so as to the normal direction of the substrate 17 is not parallel to the direction of the ion beam of the species to be deposited 16, as illustrated in FIG. 3. The angle between the normal of the substrate and the direction of the ion beam of the species to be deposited is defined as a deposition angle α. At the film formation angle larger than a certain angle, the film deposition proceeds nonuniformly owing to the self-shadowing effect to form an inclined columnar structure as illustrated in FIGS. 4A and 4B.

FIGS. 4A and 4B illustrate schematically the structure of the carbon film consisted of inclined columns of the present invention. The size, inclination angle, and other properties of the columnar-structured film depend mainly on the deposition angle. Generally, with increase of the film formation angle, the inclination angle of carbon column 41 tends to be larger and the film density tends to be lower (see FIG. 4A). At a larger deposition angle, the surface roughness tends to be larger. With decrease of the deposition angle, the inclination of carbon column 41 becomes less and the film density becomes higher. Simultaneously, the flatness of the film is improved (see FIG. 4B). At a deposition angle smaller than a certain angle, the columnar structure cannot be formed, and a dense film is formed instead.

The inclination angle of the columns does not coincide with the deposition angle, and does not depend definitely on the deposition angle. The column inclination angle depends largely on the film formation method, especially on the energy of the species to be deposited. Moreover the oblique deposition does not always cause formation of a columnar structure. In another method for forming a structurally anisotropic carbon film, an isotropic carbon film is firstly prepared and then the surface thereof is treated for providing anisotropy to the surface. For example, the surface of the isotropic carbon film is bombarded by an ion beam at a certain irradiation angle using an ion gun to provide structural anisotropy.

In the present invention, any of the above methods can be employed, insofar as the resulting structurally anisotropic carbon film is capable of controlling the orientation of the mesopores in the mesoporous silica film formed thereon. The former method is particularly preferred in which the carbon film having the inclined columnar structure is formed by the oblique deposition technique. The formation of the columnar structure can be confirmed by observing the cross-section by electron microscopy. However, electron microscopy provides only the information of the local columnar structure, and the formation of the anisotropic structure over the entire film cannot readily be confirmed. The overall structural anisotropy of the film can be evaluated using X-rays. When an oblique columnar structure is formed throughout the film, and the columns are inclined in a certain direction, the X-ray introduced at a grazing incidence angle onto the carbon film surface is scattered at a higher intensity selectively in a certain direction in the X-ray scattering intensity profile recorded in a reflection mode. In the present invention, such carbon films that cause anisotropic X-ray scattering are particularly preferred.

The inclination angle of the column of the non-single-crystalline carbon film having structural anisotropy is not limited in the present invention insofar as the mesoporous silica film can be formed thereon with controlled in-plane arrangement of the mesopores. However, the oblique angle of the columnar structure cannot be arbitrarily controlled over the whole angle range by adjusting the deposition angle. The carbon films formed at larger deposition angles tend to provide mesoporous silica films with higher in-plane structural regularity.

Chemical properties of the non-single-crystalline carbon film having the structural anisotropy depend on the preparation method as well as the structure and the surface flatness of the films. The non-single-crystalline carbon having the structural anisotropy of the present invention is preferably a diamond-like carbon film containing carbon with sp³ C—C bonds. The ratio of the carbon with sp³ C—C bonds in the film depends on the film preparation method, particularly on the energy of the species to be deposited. Higher ratio of carbon with sp³ C—C bonds provides denser and harder films. In the present invention, the ratio of carbon with sp³ C—C bonds is not limited. The ratio also depends on the deposition angle, and it tends to be smaller when the deposition angle becomes higher. The ratio of carbon with sp³ C—C bonds in the film can be estimated by X-ray photoelectron spectroscopy, as described, for example, in the document of Applied Surface Science, vol. 136, pp. 105-110. According to the method, the ratio can be estimated by the measurement of the photoelectron spectrum of carbon 1s and the subsequent deconvolution into two components centered at 284.4 eV and 285.2 eV.

A particularly preferred method for forming the carbon film in the present invention is oblique filtered arc deposition. This method is known as a method of formation of diamond-like carbon, being capable of forming a carbon film having relatively high ratio of carbon with sp³ C—C bonds.

The filtered arc deposition is one of the methods of vacuum arc deposition. In this method, ions of a cathode material generated by arc discharge are accelerated by an electric field forming an ion beam with high directionality. The ion beam is deflected by a magnetic field and directed to the substrate chamber, then it impinges on the substrate to deposit the material on a substrate. This method is characterized by high ion beam energy and a high deposition rate and is suitable for forming a strong and dense film.

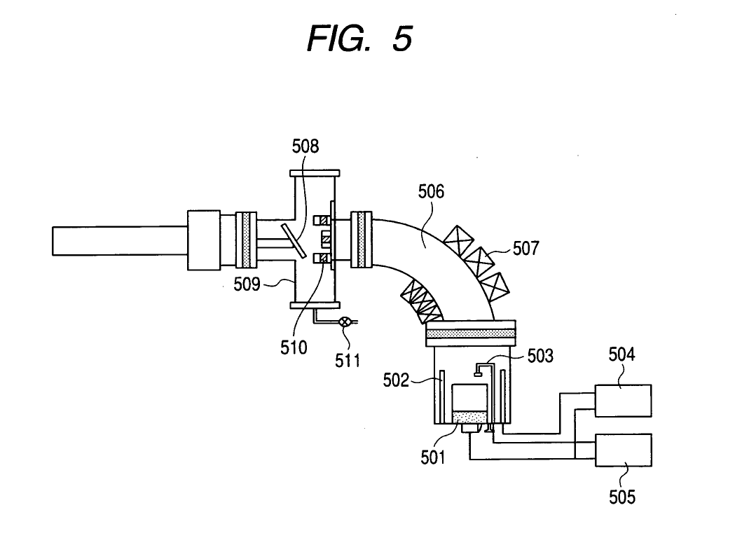

FIG. 5 illustrates schematically a system of an apparatus for the carbon film formation by filtered arc deposition in the present invention. The process of film formation with this apparatus is described below.

At cathode 501, the material of the cathode is ionized by arc discharge to generate ion plasma (hereinafter referred to as arc plasma). The cathode consists of an electrically conductive material: graphite in this invention. Plasma duct 506 is bent at an angle of 90° in FIG. 5, but is not limited thereto within the range in which the structurally anisotropic carbon film can be formed.

Trigger electrode 503 is used to induce arc plasma between the trigger electrode and cathode 501 by applying a voltage from an power source 505. by applying. A vacuum arc is generated by instantaneous contact of the trigger electrode 503 temporarily with the surface of the cathode 501. Usually a DC arc is employed, but a pulse arc can also be used.

Anode 502 is a cylindrical electrode for attracting the generated arc plasma ions from the cathode surface and accelerating the ions. A DC voltage is applied by a power source 504 between the anode 502 and the cathode 501 to accelerate the plasma ions.

The ions in the arc plasma are accelerated by the applied acceleration energy to form an ion beam, and introduced into a plasma duct 506. The plasma duct 506 is equipped by toroidal coils 507 to generate a magnetic field along the. The orbit of the ion beam is deflected by this magnetic field and is impinged on the substrate 508 in the deposition chamber. The orbit of the plasma is deflected to selectively remove undesirable particles called “droplets” which are relatively large in size and concomitantly formed by the arc discharge with the ions.

In the filtered arc deposition process, the film is deposited by an ion plasma with a high directivity, as described above. In the present invention, this filtered arc deposition is employed for the oblique film formation. For the oblique deposition, a substrate 508 is placed so as to the normal of the substrate surface is inclined with respect to the ion flux direction.

Raster scanning of the ion beam on the substrate is effective for improving the uniformity of the film thickness. For the raster scanning of the ion beam, two pairs of electromagnets 510, which are placed at the entrance of the deposition chamber, 509 are used to form magnetic fields along vertical and horizontal directions. By controlling the voltage applied to the two magnets, the ion beam is scanned on the substrate. The beam scanning is not essential. However, when a substrate with a surface curvature is used, this beam scanning with optimized conditions for the surface shape is effective.

The films prepared by this filtered arc deposition at a film formation angle of 50° or larger have a columnar structure. This is confirmed by scanning electron microscopy and by X-ray scattering intensity profile measured by introducing X-rays at the above-mentioned grazing incidence angle. The inclination angle of the formed column is smaller than the deposition angle, and the average inclination angle can be quantitatively estimated from the X-ray scattering intensity profile.

The thickness of the non-monocrystalline carbon film having structural anisotropy ranges preferably from 1 nm to 1 μm, more preferably from 5 nm to 500 nm.

In the next step, a mesostructured silica film, which is a precursor of a mesoporous silica film, is formed on the above prepared non-single-crystalline carbon film having the structural anisotropy. The preparations of mesostructured silica films are categorized roughly into 2 methods. One is based on hydrothermal synthesis, and the other is based on sol-gel chemistry. The former methods are described, for example, in the document: Chemistry of Materials, vol. 14, pp. 766-772. The latter methods are described, for example, in the document: Nature, vol. 389, pp. 364-368.

First, the hydrothermal synthesis is explained below. In this method, a substrate having a structurally anisotropic non-single-crystalline carbon film formed thereon is immersed in an aqueous reactant solution containing a surfactant, a silica source such as a silicon alkoxide, and an acid, and is kept at a temperature of about 80° C. for about 5 days to form a mesostructured silica film on the substrate. Thereby, on the surface of the structurally anisotropic non-single-crystalline carbon film, a mesoporous silica film, in which the assemblies of the surfactant molecules as the template are regularly arranged in the silica matrix, is formed.

The applicable surfactant includes cationic surfactants like a quaternary alkylammonium salt, nonionic surfactants having polyethylene oxide group as the hydrophilic group, but is not limited thereto. The length of the surfactant molecule is selected corresponding to the pore diameter of the intended meso-structure. Additives like mesitylene may be added to increase the size of the surfactant micelle. Common acid such as hydrochloric acid, and nitric acid can be used.

The mesoporous silica film formed on the substrate is washed with pure water, and air-dried to obtain the final film. In this state, the mesoporous silica film contains surfactant molecular assemblies in the mesopores.

Mesoporous silica film having hollow pores can be prepared by removing the surfactant micelles as the template from the above-prepared mesostructured silica film. The surfactant can be removed by a general method, including calcination, extraction by a solvent, oxidation and decomposition by ozone, and so forth.

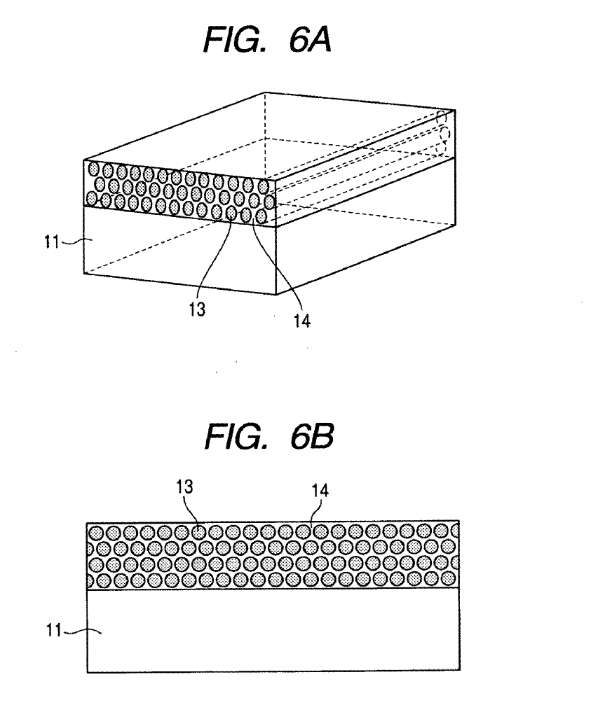

For example, the surfactant can be removed completely without affecting the mesostructure by calcining at 350° C. for 4 hours. By low temperature calcinations, only the surfactant is removed, leaving the diamond-like carbon remaining on the substrate. By calcining at a higher temperature, for example, at 600° C. for 10 hours, not only the surfactant but also the carbon film is removed. Since the thickness of the carbon film is very thin, the carbon film can be removed without peeling the mesoporous silica film from the substrate, when substrates such as silicon or quartz glass, which allow the formation of chemical bond with the mesoporous silica film, was used. In this case, the final mesoporous silica film is formed directly on the substrate as schematically illustrated in FIGS. 6A and 6B. At such calcination temperature range, the porous structure of the mesoporous silica film is not destroyed.

When the surfactant is removed by solvent extraction, the carbon film is left on the substrate.

Next, the sol-gel method for the mesoporous silica film formation is explained. In this method, a substrate is coated with a precursor solution containing a surfactant at a concentration lower than the critical micelle concentration and a silica precursor by spin coating, dip coating, or the like. The solvent of the solution is a mixture of an organic solvent and water. A regular mesostructure is formed with the increase of the surfactant concentration by the solvent evaporation during the coating process. Alcohol is preferably used as the organic solvent. Because this method can be conducted under mild reaction conditions, the limitation of the applicable substrate is less. This method has another advantage of shorter processing time.

Spin coating or dip coating can be conducted with a common apparatus without limitation. A unit for controlling the temperature of the solution, or a unit for controlling the temperature and humidity in the coating atmosphere may be employed, if necessary.

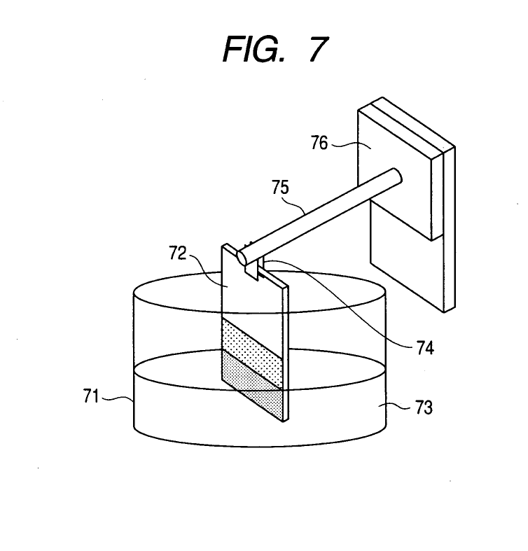

An example is described for formation of a mesoporous silica film by dip coating. FIG. 7 illustrates schematically a dip coating apparatus used in the present invention. In FIG. 7, the numerals denote the followings: 71, a vessel; 72, a substrate on which a structurally anisotropic non-single-crystalline carbon film has been formed; and 73, a precursor solution. Precursor solution 73 is a solution in a mixed solvent of an organic solvent and water containing a surfactant at a concentration lower than the critical micelle concentration and a silica precursor, and containing further an acid as a catalyst for hydrolysis and polycondensation.

The organic solvent is usually an alcohol, including preferably ethanol, 1-propanol, and 2-propanol. Common acid such as hydrochloric acid and nitric acid can be used as the acid.

The preferred surfactant includes, similarly as in the film formation by hydrothermal synthesis, cationic surfactants like a quaternary alkyl ammonium salt, nonionic surfactants having polyethylene oxide group as the hydrophilic group, but the surfactant is not limited thereto. The length of the surfactant molecule used is selected corresponding to the intended mesostructure and pore size. For a larger diameter of the surfactant micelle, an additive like mesitylene may be added. The concentration of the surfactant is adjusted suitably in consideration of the solubility of the surfactant in the solvent, the critical micelle concentration in the solution, and other factors. The substrate 72 on which the mesoporous silica film is to be formed is fixed to a rod 75 by a holder 74, and is moved up and down by a Z-stage 76. The substrate coated with the precursor solution is preferably dried in an air-conditioned chamber. After the drying process, the film may be aged in a high-humidity atmosphere. In this state, the mesoporous silica film has the surfactant assemblies in the mesopores.

Mesoporous silica films having hollow pores can be prepared by removing the surfactant from the film prepared above. The removal of the surfactant can be conducted, similarly as in the hydrothermal synthesis, by a general method such as calcination, extraction by a solvent, and oxidation-decomposition by ozone.

The porous structure of the mesoporous silica film of the present invention can be estimated by transmission electron microscopy and X-ray diffraction analysis. In the most effective method for the observation by transmission electron microscopy, a thin slice of the sample is prepared and the structure of the film cross-section is directly observed. In this observation, plural specimens are prepared by slicing in plural directions in consideration of the arrangement direction of the mesopores, and are observed. The structure of the pores is estimated comprehensively from plural images.

In the mesoporous silica film of the present invention, the mesopores are arranged in the plane of the film. Therefore, for estimation of the in-plane arrangement of the mesopores, in-plane X-ray diffraction analysis is useful. When the structure of the mesoporous silica film of the present invention is analyzed by the in-plane X-ray diffraction, two diffraction peaks with an interval of 180° are observed in the in-plane rocking curve for two-dimensional hexagonal structure having uniaxially aligned cylindrical mesopores, whereas six diffraction peaks with an interval of 60° are observed for the film with a three-dimensional hexagonal structure or a face-centered cubic structure in which the in-plane arrangement of the spherical pores is defined in the plane of the film.

The mesoporous silica film of the present invention is formed using surfactant-molecular assemblies as the template. The association number of the surfactant molecules in an assembly is determined definitely by the concentration and temperature and other conditions. Therefore, the mesopores of the consequent mesoporous silica film become uniform. The size and the pore size distribution are estimated from the nitrogen adsorption isotherm measurement, or the like. The pore size distribution curve of the mesoporous silica film of the present invention, which is estimated from the nitrogen gas adsorption isotherm according to a Barret-Joyner-Halenda (BJH) method, has a single peak in the range from 2 nm to 50 nm. In the obtained pore size distribution, 60% or more of the pores are in the range of 10 nm from the center value of the distribution, indicating high uniformity of the pore size.

The mesoporous silica film has a thickness ranging preferably from 5 nm to 100 μm, more preferably from 10 nm to 50 μm in the present invention.

The oriented mesoporous silica film is industrially applicable. For example, a semiconducting polymer is incorporated in the uniaxially oriented cylindrical mesopores of a two-dimensional hexagonal structure to prepare an organic-inorganic hybrid film in which the conjugated polymer chains are oriented in one direction. The hybrid film is applicable as a light-emitting element that emits polarized light, or as an organic semiconductor device utilizing the principal chain conduction. For the application of the mesoporous silica film of the present invention in combination with an organic semiconductor, the capability of forming an oriented mesoporous silica film on a substrate with a curved surface is particularly useful for making these devices on a curved substrate. Further, according to the present invention, plural regions with different in-plane orientations of the mesopores can be formed by depositing the carbon film using a patterned mask. Thereby unique devices, for example, light-emitting device that has plural regions emitting different polarized light can be prepared. Again, when the mesopores of a mesoporous silica film is used as channels for transporting substances or ions, a film that can transfer them along a curved surface can be prepared based on the technology of the present invention.

### EXAMPLES

The present invention is described below in more detail with reference to Examples without limiting the invention.

### Example 1

In this Example, on a quartz substrate of 1.1 mm thick or a silicon substrate of 0.5 mm thick, a structurally anisotropic non-single-crystalline carbon film was formed by oblique deposition by a filtered arc deposition method, and thereon a mesoporous silica film with a uniaxially oriented two-dimensional hexagonal structure was formed by hydrothermal synthesis.

The film formation was conducted with an apparatus having a system illustrated in FIG. 5. In the apparatus the plasma duct is bent at an angle of 90°. Cathode 501 is made of graphite (purity: 99.999%). Argon gas was introduced through a valve 511 into the film formation chamber for stabilization of the plasma at a partial pressure controlled at 1.0×10⁻¹ Pa.

The quartz glass substrate or the silicon substrate of 35 mm square was subjected to ultrasonic cleaning in pure water, and the surface was further cleaned in an ultraviolet ozone generator. The substrate was placed in a deposition apparatus for filtered arc deposition, and the carbon film was formed.

The substrate was set so as to the normal of the substrate with respect to the direction of the plasma (ionic carbon) from the cathode is 60°, 70°, 80°, and 85°. The arc plasma was generated at a voltage of 30 V at a current of 80 A to obtain an ion current of 200 mA. In the film formation, the carbon ion beam was scanned two-dimensionally on the substrate using the magnetic field generated by a current of 50 Hz through the 2 pairs of coils of the electromagnet equipped at the entrance of the film formation chamber. Since the deposition rate depends on the deposition angle, the deposition rate was preliminarily measured at the respective angles, and thereby the deposition time was determined for the respective angles to obtain a film with a thickness of 150 nm.

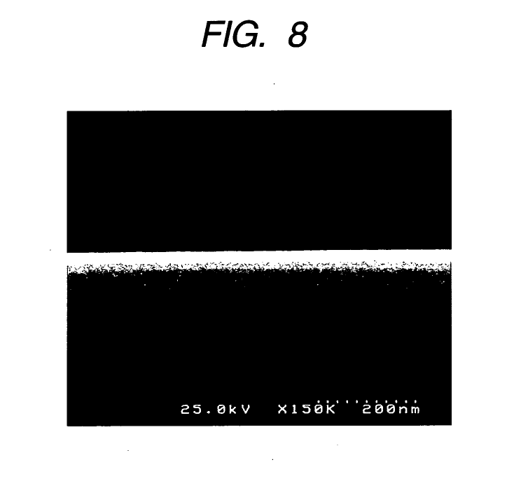

FIG. 8 shows the scanning electron micrograph (SEM) of a cross-section of the carbon film deposited at the deposition angle of 80°. In the cross-section of the film, oblique parallel streaks are observed, whereby the columnar structure of this carbon film is confirmed. This film is dense without gaps between the columns, which is confirmed by the SEM image. Further, high flatness of the film was confirmed by the SEM images of the cross-section and the surface. The carbon films formed at the other deposition angles (60°, 70°, and 85°) gave basically the same SEM photographs as in FIG. 8, showing the columnar structure of the film.

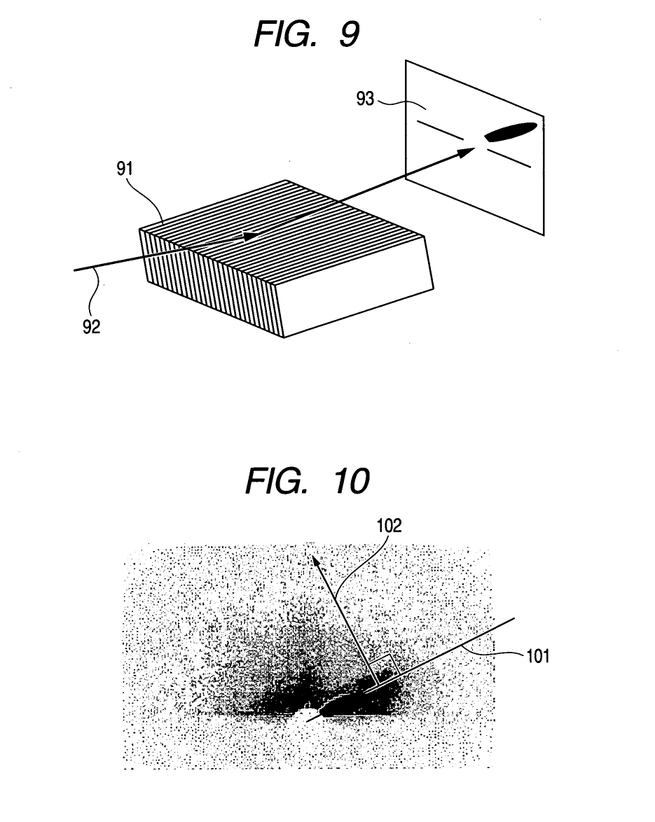

The structural anisotropy, namely the oblique columnar structure inclining in one direction, of the carbon film formed at the angle of 80° in this Example can be estimated using X-rays also. FIG. 9 illustrates an arrangement for introducing an X-ray beam at a grazing incidence angle onto the structurally anisotropic non-single-crystalline carbon film and measuring the scattered X-ray intensity to obtain a pattern. As illustrated in FIG. 9, an X-ray beam 92 is introduced in a direction perpendicular to the deposition direction at a grazing incidence angle, that is, in a direction nearly parallel to the substrate surface, and the scattered X-ray profile was recorded in a reflection mode with an imaging plate 93.

FIG. 10 shows the obtained profile. FIG. 10 shows the pattern obtained by introducing an X-ray beam at a grazing incidence angle onto the structurally anisotropic non-single-crystalline carbon film prepared in Example 1 and measuring the scattered X-ray intensity in a reflection mode. The inclination angle of the columns estimated can be estimated from the pattern.

In FIG. 10, the scattered light is selectively intensified in one direction 101. This is caused by the columnar structure, which columns are parallel each other at a uniform inclination angle. The direction 102, perpendicular to the above-mentioned direction 101 indicates the column inclination angle. This angle coincides well with the column inclination angle estimated from the SEM image in FIG. 8. The carbon films prepared at the other deposition angles (60°, 70°, and 85°) gave similar patterns substantially, which show that any of the films has a columnar structure having a uniform inclination angle. The films of this Example were examined by X-ray diffraction analysis. Thereby the diffraction patterns of crystalline graphite or diamond were not observed. Thus the carbon consisting the film was found to be amorphous.

Next, the carbon films were analyzed by X-ray photoelectron spectroscopy to characterize the bonding state of the carbon, by measuring the C is spectrum. The obtained spectra were all asymmetric, and could be deconvolved into two components: an sp² component centered at 288.4 eV and an sp³ component centered at 285.2 eV. This shows that any of the carbon films prepared in this Example is a diamond-like carbon film containing sp³ C—C bond. The proportion of the sp³ C—C bond can be calculated as the ratio of the area of the deconvolved sp³ component centered at 285.2 eV to the total peak area. In the carbon film formed at the deposition angle of 80°, the proportion of the sp³ C—C bond was found to be about 30%. This proportion tends to increase with the decrease of the deposition angle. The film formed at the deposition angle of 60° contained the carbon having sp³ C—C bonds at a ratio of about 40%.

As described above, the formation of a non-single-crystalline carbon film having structural anisotropy, that is, a uniformly inclined columnar structure, by the oblique filtered arc deposition method was confirmed.

The surface of the carbon film formed as described above was observed by atomic force microscopy. The measurement was conducted with a NanoNavi-scanning probe microscope (made by SII Nano Technology Co.) using an SI-DF-20 cantilever (made by SII Co.) at a frequency modulation mode in a scanning region of 300 nm×300 nm. As the result, the anisotropic surface roughness was observed which runs perpendicular to the vapor deposition direction. Table 1 shows the measured roughness of the surface in terms of RMS (root-mean-square).

TABLE 1

| Film | | | | | |
|---|---|---|---|---|---|
| formation | | | | | Standard |
| angle | a | B | C | Average | deviation |
| 60 | 0.1503 | 0.1626 | 0.1622 | 0.1584 | 0.0070 |
| 70 | 0.1796 | 0.1915 | 0.1754 | 0.1822 | 0.0084 |
| 80 | 0.3212 | 0.2768 | 0.3252 | 0.3077 | 0.0269 |
| 85 | 0.255 | 0.269 | 0.2841 | 0.2694 | 0.0146 |

The above results show that the carbon film formed by the oblique filtered arc deposition method has an extremely flat surface. However, the surface has anisotropic morphology, and the surface roughness is larger at the larger deposition angle, excepting that, at the deposition angle of 85°, the roughness of the film was smaller than that formed at 80°.

In the next step, a mesoporous silica film was formed on the carbon film. The surfactant used in this Example was a nonionic surfactant, polyoxyethylene-10-cetyl ether (C₁₆EO₁₀, trade name: Brij56, Aldrich Co.). This surfactant was dissolved in pure water, and thereto hydrochloric acid and tetraethoxysilane (TEOS) were added to obtain the final component with a mole ratio of TEOS:H₂O:HCl:C₁₆EO₁₀=0.10:100:3.0:0.11.

In this solution, the above-mentioned substrate having the structurally anisotropic non-single-crystalline carbon film formed thereon was held with the surface of the carbon side directed downward at 80° C. for three days to form a mesoporous silica film. The substrate taken out from the solution was washed well with pure water, and was air-dried. Thereby a transparent film with a uniform interference color of about 400 nm thick was formed.

According to the XRD analysis (Cu Kα line), this film provided a strong diffraction peak at 2θ=2.11°, and the structural period along the thickness direction was estimated to be 4.2 nm. According to the examination of this film by cross-sectional transmission electron microscopy, the thin film was found to have a two-dimensional hexagonal structure of honeycomb-packed cylindrical pores. The pores were found to be formed regularly in the entire thickness of the film.

The in-plane orientation of the pores in the films was examined by in-plane X-ray diffraction analysis. All the mesoporous silica films formed on the obliquely deposited carbon films gave one diffraction peak when the film was fixed with its deposition direction kept perpendicular to the X-ray beam projection direction, but gave no diffraction peaks when the film is fixed with its deposition direction kept parallel to the X-ray beam projection direction. The above results suggest that the pores of mesoporous silica films with a two-dimensional hexagonal structure formed on the carbon film by the oblique filtered arc deposition are anisotropically oriented.

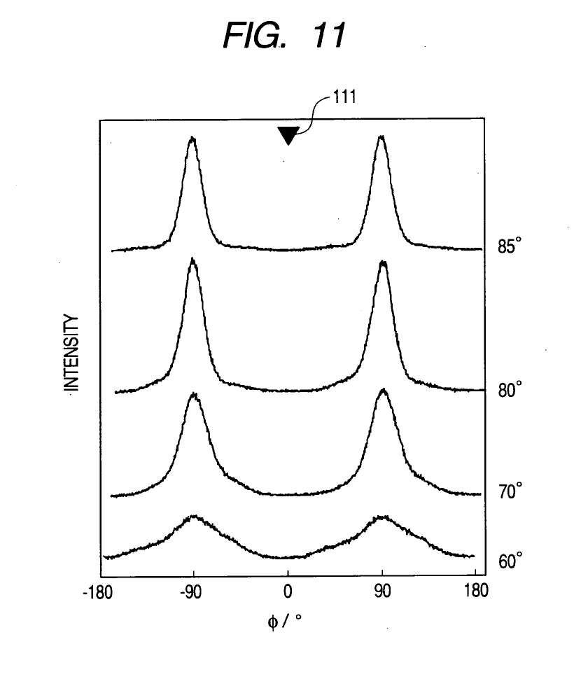

For the quantitative evaluation of the orientation, in-plane X-Ray diffraction rocking curve was measured. In this method, the detector was fixed at the diffraction peak position recorded at the geometry that the deposition direction of the carbon films is perpendicular to the projected direction of the incident X-rays, and the sample was rotated along the surface normal. Thereby, as shown in FIG. 11, the mesopores were found to be oriented uniaxially in the direction perpendicular to the deposition direction 111. From this result, in combination with the observation by cross-sectional transmission electron microscopy, the orientation of the mesopores was found to be controlled throughout the produced mesoporous silica film. As understood from FIG. 11, the orientation controllability depends on the inclination angle of the substrate in the carbon film deposition, and the it tends to be higher in the order: 85°≈80°>70°>>60°

This orientation controllability is in the same tendency as the roughness of the film surface shown in Table 1. The mechanism of the orientation of the mesopores on the carbon film of the present invention has not completely understood. The inventors of the present invention presume that the orientation of the mesopores can be determined by the anisotropy of the carbon film surface and the roughness of the structure, namely the height of the roughness as one factor.

The small difference in the orientation controllability between the deposition angles of 85° and 80° shows that the present invention is applicable to the uniformly aligned mesoporous silica film formation on a curved substrate.

The films prepared above were calcined in air under the conditions of 350° C. for 4 hours, or 600° C. for 10 hours to remove the surfactant. The calcination scarcely affected to the appearance of the mesoporous silica films. The samples calcined under the respective conditions were examined by X-ray diffraction analysis. It was found that the regular porous structure was kept in the samples calcined under the above two temperature-time conditions, although the structure period of the film in the thickness direction was decreased by about 10% to 13%. Further, the complete retention of the in-plane orientation distribution of the mesopores was confirmed by in-plane X-ray diffraction analysis. The structural period in the plane of the film was not changed by calcination. According to examination by cross-sectional transmission electron microscopy, the carbon film on the substrate was remaining by calcination at 350° C. for 4 hours, whereas the carbon film was removed from the substrate by the calcination at 600° C. for 10 hours resulted in the formation of a hollow mesoporous silica film directly on the substrate.

As described above in this Example 1, a mesoporous silica film having cylindrical mesopores can be prepared on a structurally anisotropic non-single-crystalline carbon film, with the mesopores arranged in a direction determined by the structural anisotropy of the carbon film throughout the entire substrate.

### Example 2

In this Example, a mesoporous silica film with a three-dimensional hexagonal structure, in which the in-plane arrangement of the spherical mesopores is controlled, is prepared on a structurally anisotropic non-single-crystalline carbon film by hydrothermal synthesis, in the same manner as in Example 1. A quartz substrate of 1.1 mm thick or a silicon substrate of 0.5 mm thick were used as the substrate, and the carbon film was formed by an oblique filtered arc deposition method.

First, a diamond-like carbon film was formed on the above-mentioned substrate using the same filtered arc deposition apparatus as in Example 1 at the deposition angle of 75°. This film had an inclined columnar structure with structural anisotropy, and contained sp³ C—C bonded carbon as in Example 1.

A mesoporous silica film was formed on this carbon film.

The surfactant used in this Example was the nonionic surfactant, polyoxyethylene-10-cetyl ether (C₁₆EO₁₀), the same one as used in Example 1. This surfactant was dissolved in pure water, and thereto hydrochloric acid and tetraethoxysilane (TEOS) were added to obtain the final component with a mole ratio of TEOS:H₂O:HCl:C₁₆EO₁₀=0.10:100:3.0:0.002. The concentration of the surfactant was 1/50 times that of Example 1 for producing the film of the two-dimensional hexagonal structure.

In this solution, the above-mentioned substrate having the structurally anisotropic non-single-crystalline carbon film formed thereon was held with the surface of the carbon side directed downward at 80° C. for 3 days for the formation of a mesoporous silica film. The substrate taken out from the solution was washed well with pure water, and was air-dried. Thereby a transparent film showing a uniform interference color with about 300 nm thickness was formed.

According to X-ray diffraction analysis (Cu Kα line), this mesoporous silica film provided a strong diffraction peak at 2θ=2.04°, and the structural period along the thickness direction was estimated to be 4.3 nm. According to the examination of this film by cross-sectional transmission electron microscopy, this film was found to have a three-dimensional hexagonal structure consisted of close-packed spherical pores. The pores were found to be formed regularly in the entire thickness of the film.

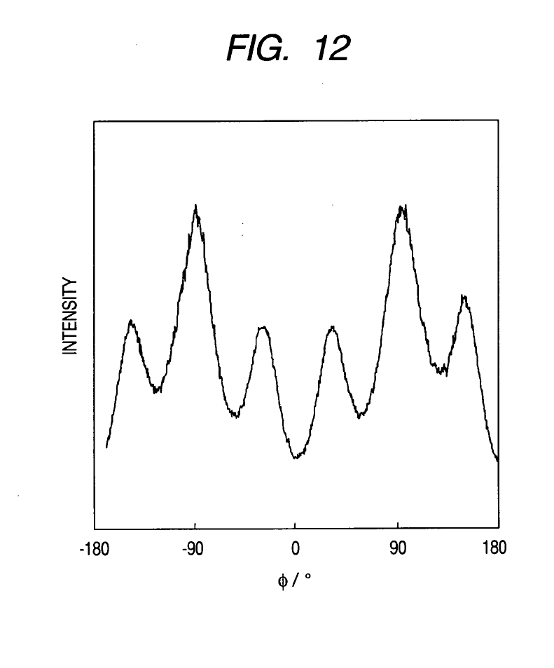

The in-plane orientation of the pores in the film was examined by in-plane X-ray diffraction analysis. The in-plane X-ray diffraction rocking curve was recorded according to the same procedure as in Example 1 As the result, 6 diffraction peaks were observed at an interval of 60° as shown in FIG. 12. This shows the controlled in-plane arrangement of the spherical pores throughout the film.

The film prepared above was calcined in the air at 400° C. for 5 hours to remove the surfactant. The calcination scarcely affected the appearance of the mesoporous silica film. The samples after calcination was examined by X-ray diffraction analysis and it was found that the regular pore structure was kept although the structural period in the film thickness direction was decreased by about 12%. Further, it was found by in-plane X-ray diffraction analysis that the structural period of the mesopores in the plane of the film was also unchanged, and the six-fold symmetric in-plane regularity was retained.

As described above in this Example, a mesoporous silica film having spherical mesopores can be prepared, on a structurally anisotropic non-single-crystalline carbon film, with the mesopores arranged in a direction determined by the structural anisotropy of the carbon film throughout the substrate.

### Example 3

In this Example, in the same manner as in Example 1, on a quartz substrate of 1.1 mm thick or a silicon substrate of 0.5 mm thick, a structurally anisotropic non-single-crystalline carbon film was formed by oblique deposition by a filtered arc deposition method, and thereon a mesoporous silica film having a uniaxially oriented two-dimensional hexagonal structure was formed by a sol-gel method.

a carbon film was formed using the same filtered arc deposition apparatus on the above-mentioned substrate, as in Example 1 at the deposition angle of 80°. This film had an inclined columnar structure, and contained sp³ C—C bonded carbon as in Example 1.

A mesoporous silica film was formed on this carbon film.

The surfactant used in this Example was the nonionic surfactant, polyoxyethylene-10-cetyl ether (C₁₆EO₁₀), the same one as used in Example 1. This surfactant was dissolved in ethanol, and thereto hydrochloric acid and tetraethoxysilane (TEOS) were added to obtain the final component with a mole ratio of TEOS:ethanol:H₂O:HCl:C₁₆EO₁₀=1.0:22:5.0:0.004:0.08. In this sol-gel method, an alcohol was used as the main solvent, and the concentration of the acid was lowered remarkably than in the hydrothermal synthesis.

The substrate with the carbon film coating was coated with the solution by dip coating. The apparatus employed for the dip coating is schematically illustrated in FIG. 7. The withdrawal speed was controlled at 1 mm/s. The substrate coated with the solution was held in an atmosphere of 20° C. and the relative humidity 40% for 12 hours to obtain a mesoporous silica film with a thickness of about 250 nm. The formed mesoporous silica film contains the surfactant in the pores.

According to the X-ray diffraction analysis, this mesoporous silica film provided a strong diffraction peak at 2θ=1.94°, and the structural period was estimated to be 4.7 nm in the thickness direction. According to the characterization of the cross-section of this film by transmission electron microscopy, this mesoporous silica film was found to have the regular structure throughout the film thickness.

The in-plane orientation of the pores in the mesoporous silica film was examined by in-plane X-ray diffraction analysis. The mesoporous silica film formed on the carbon film in this Example gave a diffraction peak when the film was fixed with its deposition direction kept perpendicular to the projected direction of the incident X-ray beam, but gave no diffraction peak when the film is fixed with its deposition direction kept parallel to the projected direction of the incident X-ray beam. This result is the same as that of the mesoporous silica film prepared by hydrothermal synthesis described in Example 1. The above results suggest that the pores in the mesoporous silica film with the two-dimensional hexagonal structure formed on the carbon film by the sol-gel method are oriented with high anisotropy.

Next, the in-plane rocking curve was obtained in the same manner as in Example 1. Thereby the mesopores were found to be oriented uniaxially in the direction perpendicular to the deposition direction with a narrow orientation direction.

This film was calcined in air at 400° C. for five hours to remove the surfactant. The film after calcination was evaluated by X-ray diffraction analysis. Thereby a diffraction peak was observed at an angle corresponding to d=2.7 nm. This shows that the regular porous structure was retained even after calcination although the structural period changed remarkably in the film thickness direction. According to characterization of the calcined mesoporous silica film by in-plane X-ray diffraction analysis, the orientation of the cylindrical pores was little affected by the heat-treatment. The structural period in the in-plane direction was not changed by the heat treatment, although the structural period in the film thickness direction. changed remarkably

In this Example, a mesoporous silica film, in which the orientation of the cylindrical mesopores is controlled in one direction in the plane of the film over the entire substrate is formed by use of a structurally anisotropic non-single-crystalline carbon film.

### Comparative Example 1

On a quartz substrate of 1.1 mm thick or a silicon substrates of 0.5 mm thick, a structurally anisotropic SiO₂ film was formed by oblique electron beam evaporation, and thereon a mesoporous silica film was formed by hydrothermal synthesis.

The obliquely evaporated SiO₂ film was formed by a usual electron-beam evaporation. In the oblique evaporation, the substrate was held at a distance of 80 cm from the evaporation source so as to the normal of the substrate with respect to the evaporation direction is 70°. Thereby the SiO₂ film with the thickness of 100 nm was deposited on the substrate.

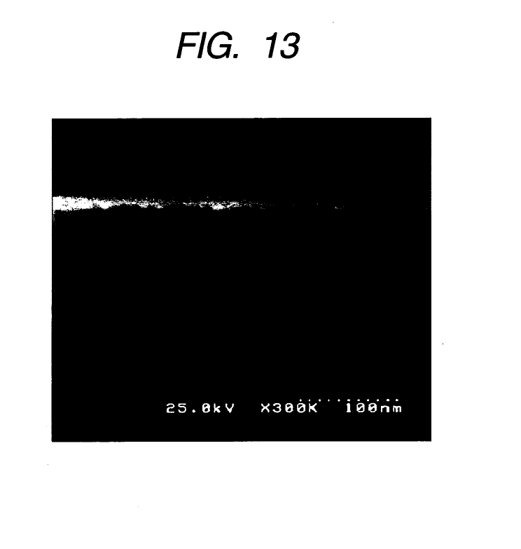

FIG. 13 shows a scanning electron micrographs of the cross-section of the obtained obliquely evaporated SiO₂ film. From this electron micrograph, the obliquely evaporated SiO₂ film has an inclined columnar structure with the inclination angle nearly equal to that of the carbon film formed in Example 1. This SiO₂ is amorphous, and has voids between the columns owing to the lower deposition energy of the deposited species than in the filtered arc deposition.

The formation of a mesoporous silica film was tested on this obliquely evaporated SiO₂ film. Under the same conditions as in Example 1, the above obliquely evaporated SiO₂ film was held in an acidic reactant solution containing the silica source and the surfactant at 80° C. for 3 days.

The substrate was taken out from the solution, and was washed with water and air dried. The substrate became opaque and a white material formed on the surface. The surface was lusterless and a continuous thin film was not formed on the surface. By the observation using an optical microscope, the substrate surface was found to be filled with particles at a micron scale, but the intended mesoporous silica film was not formed.

This Comparative Example shows that the oriented mesoporous film cannot always be formed on a structurally anisotropic film with a columnar structure. It depends on the material of the anisotropic film.

The oriented mesoporous silica film of the present invention is useful in various industrial application fields. For example, semiconducting polymer are introduced into the oriented cylindrical mesopores of the two-dimensional hexagonal structure to form an organic-inorganic hybrid film in which a conjugated polymer chains are oriented in one direction along the pores. This hybrid film can be used as a light emitting device that emits polarized light, or an organic semiconductor device based on the principal chain conduction. For applications of the mesoporous silica film of the present invention in combination with an organic semiconductor, the present invention is particularly effective in forming such devices on a non-planar substrate, since the present invention enables formation of the oriented mesoporous silica film even on a curved surface.

Further, plural regions with different in-plane orientations of the mesopores can be formed by depositing the carbon film using a patterned mask. By this method, for example, a light-emitting device that has plural regions emitting different polarized light can be prepared.

This application claims the benefit of Japanese Patent Application No. 2008-310293, filed Dec. 4, 2008, which is hereby incorporated by reference herein in its entirety.

1.-5. (canceled)

6. A process for producing a mesoporous silica film, comprising the steps of:
forming a non-single-crystalline carbon film having structural anisotropy on a substrate by an oblique filtered arc deposition technique, and
forming, on the carbon film, a mesostructured silica film with controlled in-plane orientation of the mesopores containing surfactant molecule assemblies, wherein
the carbon film is formed by the oblique filtered arc deposition technique at a deposit angle of 50° or larger and less than 90°.

7. (canceled)

8. The process for producing a mesoporous silica film according to claim 6, wherein the mesostructured silica film is formed by hydrothermal synthesis.

9. The process for producing a mesoporous silica film according to claim 6, wherein the mesostructured silica film is formed by a sol-gel method.

10. The process for producing a mesoporous silica film according to claim 6, the process further comprising the step of removing the surfactant from the pores.

11. The process for producing a mesoporous silica film according to claim 6, wherein
the carbon film is formed by the oblique filtered arc deposition technique at a deposit angle of 70° or larger and less than 90°.
